(19) United States
(12) Patent Application Publication
(10) Pub. No.: US 2007/0197054 A1
(43) Pub. Date: Aug. 23, 2007

(54) Coaxial connector

(76) Inventor: Peter Jordan, Basingstoke (GB)

Correspondence Address: LEON D. ROSEN;FREILICH, HORNBAKER & ROSEN, Suite 1220, 10960 Wilshire Blvd., Los Angeles, CA, 90024, US

(21) Appl. No.: 11/706,765

(22) Filed: Feb. 15, 2007

(30) Foreign Application Priority Data
Feb. 22, 2006 (GB) GB 0603566.1

(51) Int. Cl. H05K 1/00

(52) U.S. Cl. 439/63

(57) ABSTRACT

A coaxial cable connector comprises an injection moulded substrate (79) and a plated conductive pattern formed directly on the substrate, wherein the conductive pattern comprises: a plurality of first tracks (11a) each terminating at one end in a connecting portion (13) for connection to an inner conductor of a coaxial cable and at the other end in a pad (15) for contacting a mating connector; and a plurality of second tracks each terminating at one end in a connecting portion for connection to an outer conductor of a coaxial cable and at the other end in a pad for contacting a mating connector. A PCB connector, comprising a moulded plastics component having spring contacts, mates with the cable connector.

### CROSS-REFERENCE

Applicant claims priority from Great Britain patent application SN 0603566.1 filed 22 Feb. 2006.

### BACKGROUND OF THE INVENTION

This invention relates to a coaxial connector, and in particular to a so-called micro-coaxial connector. The invention also relates to a connector arrangement comprising a micro-coaxial connector.

A known micro-coaxial connector arrangement typically comprises a cable connector and a PCB connector. The cable connector and the PCB connector each comprise a plurality of stamped metallic contacts arranged in a moulded plastics component. The plastics component may be moulded with the contacts in place, or else the pins may be stitched to the plastics component after moulding. Separate contacts are provided in each connector for the signal and ground conductors of a plurality of coaxial cables.

An important application of micro-coaxial connectors is in devices having liquid crystal displays (LCDs), where they are used to connect the LCD device to a PCB. The trend towards miniaturisation of electronics devices having LCDs has created a need for micro-coaxial connectors that are correspondingly reduced in size. There is also a general desire to reduce the complexity of micro-coaxial connectors in order to improve reliability and reduce cost.

### SUMMARY OF THE INVENTION

According to the invention, there is provided a coaxial connector comprising an injection moulded substrate and a plated conductive pattern formed directly on the substrate, wherein the conductive pattern comprises a plurality of first tracks each terminating at one end in a connecting portion for connection to an inner conductor of a coaxial cable and at the other end in a pad for contacting a mating connector.

The invention thus provides a connector suitable for use as a micro-coaxial cable connector for a plurality of cables. Because the conductive pattern is plated directly on the substrate, for example using moulded interconnect device (MID) technology, a complexity of the connector as compared to conventional connectors is reduced. By using a plated conductive pattern, the size of the connector can also be reduced, both in terms of profile and the pitch of adjacent conductive tracks.

Preferably, the conductive pattern further comprises a plurality of second tracks each terminating at one end in a connecting portion for connection to an outer conductor of a coaxial cable, the other end being connected to a pad for contacting a mating connector.

The first tracks and the second tracks may be arranged alternately across the substrate. Thus, if the first tracks are used to carry signals and the second tracks are grounded, each of the signal tracks is surrounded on both sides by a grounded track. In this way, signal interference can be reduced, particularly for high frequency signals.

The second tracks may be connected together by a link track that extends perpendicular to the second tracks. The second tracks may then share an enlarged pad for contacting a mating connector.

In certain embodiments, the connector may have a conductive cover which encloses the substrate, the conductive cover being electrically connected to the second tracks. The conductive cover may be a metal shell. An insulating film may be disposed between the substrate and the conductive cover for insulating the conductive cover from the signal tracks. The insulating film may also extend out of the conductive cover for providing strain relief for connected cables.

The second tracks may be arranged in groups, the tracks of each group then being connected together by a respective link track extending perpendicular thereto. In use, the grouped second tracks perform a variety of different functions, for example carrying current for powering a device or providing grounds at different potentials.

The connecting portions for the first and second tracks may be spaced across both upper and lower sides of the substrate, thereby providing two rows of connections. The first and second tracks then extend along the sides. Pads for the first and second tracks may be arranged in first and second rows, the first and second rows being associated with the connecting portions on the upper and lower sides of the substrate, respectively.

In embodiments, the rows of pads for the first and second tracks are formed on opposite sides of a downwards extending protrusion of the substrate. The protrusion may have a tapered wedge shape, being wider at its end than at its root. In this way, opposing lateral forces on the rows of pads cause a net downwards force on the substrate for maintaining engagement with a mating connector.

The invention also provides a connector arrangement comprising a cable connector as described above and a mating connector, wherein the mating connector comprises two rows of resilient contacts arranged for contacting and applying opposing lateral forces to respective rows of the pads of the first connector, such that engagement of the first conductor can be positively maintained.

The mating connector may be formed from a moulded plastics component with stamped spring contacts. The mating conductor may be adapted for connection to a printed circuit board.

The cable connector and the mating connector may have a latching mechanism for latching the connectors together in the engaged position. The mechanism may comprise laterally extending rails provided on each end of the mating connector. Then, when the protrusion of the cable connector is inserted into the mating connector, latching elements of the cable connector engage with the rails of the mating connector. The latching elements may, for example, be protrusions, notches or tabs extended from a metallic cover of the cable connector.

The rails of the mating connector and/or the latching elements of the cable connector may have some resilience, so that the connectors can only be unlatched by biasing the resilient elements. The latching mechanism may be arranged so that a special tool is required to unlatch the connectors, for example by inserting the tool into apertures in one of the connectors to bias the resilient elements.

The novel features of the invention are set forth with particularity in the appended claims. The invention will be best understood from the following description when read in conjunction with the accompanying drawings.

### DESCRIPTION OF THE DRAWINGS

A specific embodiment of the invention will now be described, by way of example only, with reference to the accompanying drawings, in which:

FIG. 1 is an isometric view of a cable connector according to the invention;

FIG. 2 is an exploded isometric view of the cable connector shown in FIG. 1, which shows the main components of the connector;

FIGS. 3A and 3B are isometric views of an upper and lower side, respectively, of elements of the cable connector shown in FIG. 1;

FIG. 4 is a view, comparable to FIG. 3A, of elements of a second cable connector according to the invention;

FIG. 5 is an isometric view of a PCB connector for use with the cable connector shown in FIG. 1; and

FIG. 6 is a cross sectional view showing the connectors of FIGS. 1 and 5 in the mated condition.

### DESCRIPTION OF THE PREFERRED EMBODIMENT

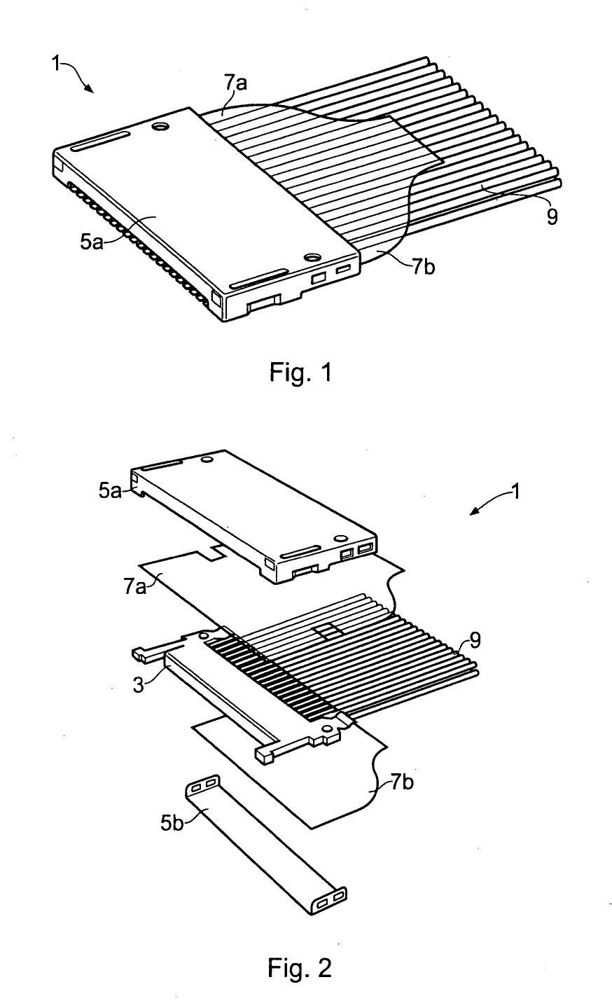

FIG. 1 shows a cable connector 1 according to the invention. FIG. 2 is a more detailed diagram of the cable connector 1 in exploded form. For assistance in recognising the various elements of the connector 1, the Figures include an array of coaxial cables 9 which are connected to the connector 1 in two rows. These cables 9 do not, however, form part of the connector 1.

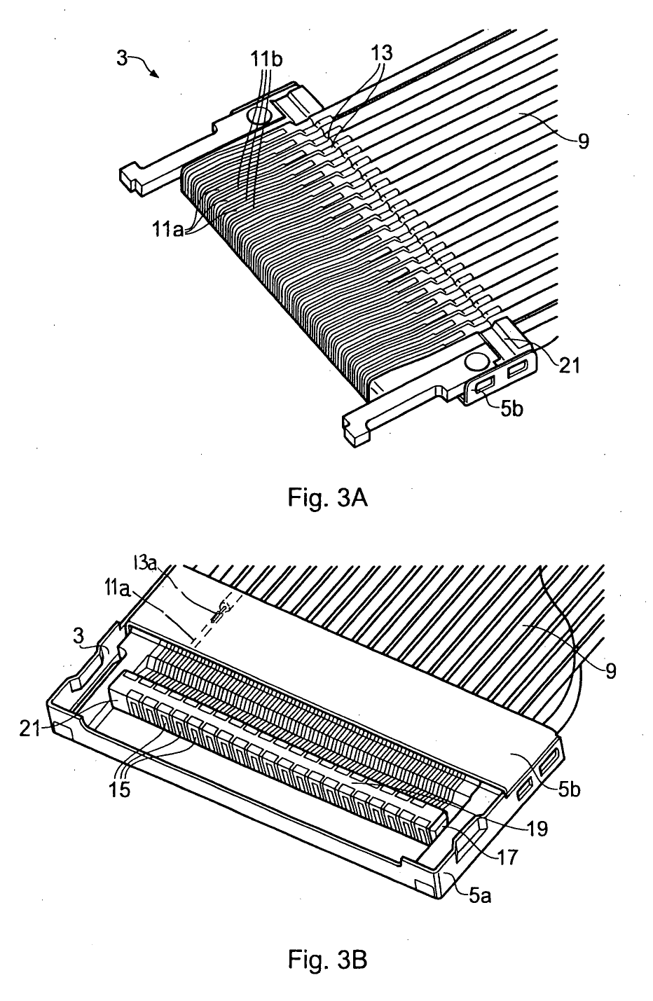

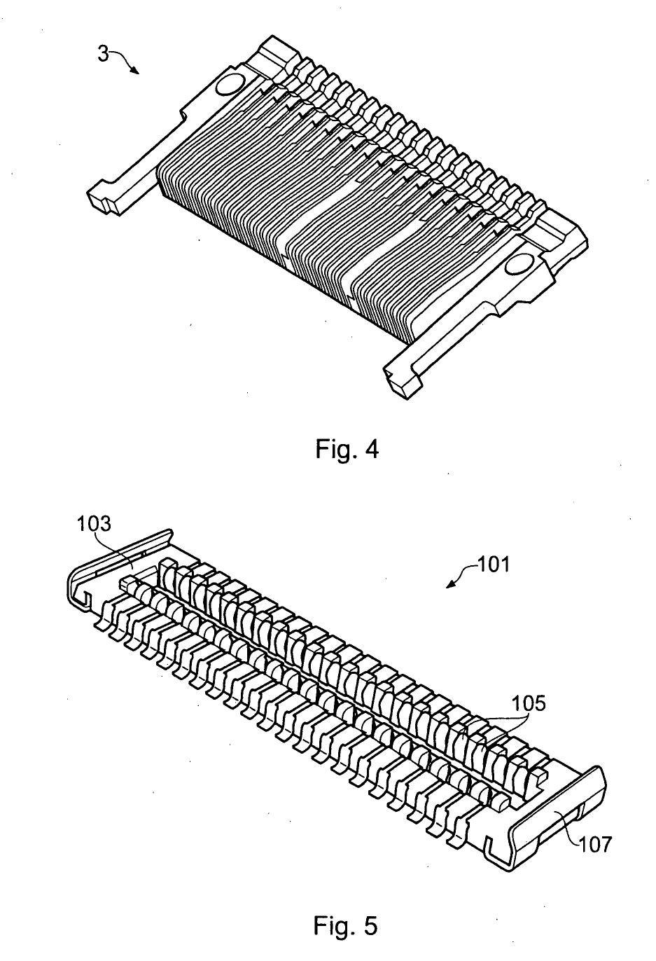

The connector 1 is a micro-coaxial connector comprising an injection moulded plastic substrate 3 having a plated conductive pattern formed directly thereon. The shape and configuration of the plated conductive pattern will be described in detail at a later stage with reference to FIGS. 3A, 3B and 4. The plated conductive pattern is formed using a technology called Moulded Interconnect Device (MID) technology.

MID technology involves processing the injection moulded plastic substrate so that elements of its surface are selectively plated with electroless copper. The layer of copper is then built up or may alternatively be plated over with another metal such as nickel or gold. The areas to be selectively plated may be defined by over-moulding a platable plastic component with a patterned layer of nonplatable plastic, or by selectively scanning the plastic substrate with a laser to release copper ligands for facilitating plating. Other techniques for selectively plating the plastic substrate, as well as other aspects of MID technology, will be known to those skilled in the art.

The connector 1 also comprises a two-part metallic shell 5a, 5b that encloses the moulded plastic substrate. Between the moulded plastic substrate 3 and the shell 5a, 5b there are also disposed dielectric polymer films 7a, 7b. The films 7a, 7b electrically insulate the moulded plastic substrate 3 from the shell 5a, 5b and also provide a degree of strain relief for the cables 9. The films 7a, 7b may have an adhesive layer (not shown) on one or both sides to hold them in position.

FIGS. 3A and 3B show in detail an upper and lower side, respectively, of the moulded plastic substrate 3 shown in FIGS. 1 and 2. As can be seen from the Figures, the plated conductive pattern on the moulded plastic substrate 3 comprises a plurality of parallel tracks which extend along both sides of the substrate 3 and are distributed across the substrate 3. The tracks comprise alternate first and second tracks 11 a, 11 b, for connection to the inner and outer conductors of coaxial cables 9, respectively.

In the connector 1 shown in FIGS. 3A and 3B, there are tracks for connection to a total of 40 coaxial cables arranged in two rows. Connectors of different sizes are possible, although the invention is most suited to connectors for at least 10 coaxial cables.

Each of the first and second tracks 11 a, 11 b terminate at one of their ends in a solder terminal 13 for connection to the inner and outer conductors of the coaxial cables 9. The solder terminals 13 are arranged in two rows, one for the tracks on the upper surface of the substrate 3 and one for the tracks on the lower surface of the substrate 3. The row of solder terminals 13a for the tracks on the lower surface are indicated in FIG. 3B.

The first tracks 11 a terminate at their other end in pads 15 for contacting a mating connector. The pads 15 are also arranged in two rows, one for the tracks on the upper surface of the substrate 3 and one for the tracks on the lower surface of the substrate 3. The two rows of pads 15 are arranged on opposite sides of a downwards protrusion 17 of the substrate 3, although only one of these sides can be seen in FIG. 3B. The downwards protrusion 17 is shown as extending upwards in FIG. 3B because FIG. 3B is a view of the lower side of the substrate 3. The downwards protrusion 17 and its connection to a mating connector will be described in more detail later in this description.

The second tracks 11 b terminate in a link track 19, which extends across the end face of the downwards protrusion 17 of the substrate 3, perpendicular to the second tracks 11 b. The link track 19 extends along a space between the two rows of pads 15 for the first tracks 11a. The link track 19 electrically connects the second tracks 11 b together. The link track 19 terminates in link track pads 21 provided at both ends of the substrate 3, which are arranged on the opposing sides of the downwards protrusion 17. Link track pads 21 are also provided for electrically connecting the metallic shell 5a, 5b to the second tracks 11 b.

In use, the first tracks 11a are usually connected to the inner conductors of coaxial cables, and carry data signals. The second tracks 11b are usually connected to grounded outer conductors of coaxial cables, and the link track 19 then provides an electrical connection between the grounded outer conductors.

In some applications, it is desirable not to have an electrical connection between all of the second tracks 11 b, or alternatively it is desirable to have an electrical connection between groups of the second tracks 11 b.

The invention allows for such applications, and an example of a substrate 3 of an alternative connector having grouped second tracks 11b is shown in FIG. 4, which is an upper view of the substrate 3. As can seen from the Figure, a number of second tracks 11 b have been omitted from the substrate 3. The link track (not shown) is also broken in these regions. Consequently, the second tracks 11 b are connected together in localized groups rather than all together. This arrangement allows for different groups of second tracks 11 b to have independent ground potentials and for the use of a group of second tracks 11 b for carrying power. The second tracks 11 b may not, in this case, be electrically connected to the outer shell 5a, 5b.

FIG. 5 shows a PCB connector 101 for use with the cable connector 1 described above. The PCB connector 101 comprises a moulded plastic component 103 and a plurality of metallic spring contacts 105 arranged therein. In this respect, the PCB connector 101 is of conventional construction.

The contacts 105 of the PCB connector 101 are arranged in two rows. A first end of each contact 105 is positioned for connection to the tracks of a PCB. A second end of each contact 105 is arranged to contact a respective pad of the cable connector 1 described above. The second ends are hooked so as to provide them with resilience. In use, the hooked second ends are biased by the pads 15, 21 of the cable connector 1, and the resilience provides a force for maintaining an electrical connection during environmental vibration, etc.

It can be seen that the pitch of the contacts 105 of the PCB connector 101 is half the pitch of the tracks 11 a, 11 b of the cable connector 1. This is because the second tracks 11 b of the cable connector 1 are grouped together by the link track 19 and connected to the PCB connector 101 via a small number of link track pads 21. Individual contacts corresponding to each second track 11b of the cable connector 1 are not therefore required.

Thus, the invention employs MID technology to provide tracks within the cable connector 1 having a very low pitch, but a mating connector can use conventional stamped contacts at a higher pitch, because individual contacts corresponding to the alternate second tracks 11 b of the cable connector 1 are not required.

Referring back to FIG. 5, it can be seen that the PCB connector 101 also comprises metallic rails 107 arranged at each end of the moulded plastic component 103. The rails 107 are used for latching the cable connector 1 to the PCB connector 101 as described below.

In use, the downwards protrusion 17 of the cable connector 1 is inserted between the two rows of contacts 105 of the PCB connector 101. The downwards protrusion 17 is slightly wider that a spacing between the two rows of contacts 105 of the PCB connector 101, so that the sides, and the pads 15, 21 formed thereon, bear against the contacts 105 to resiliently bias them.

Once the protrusion 17 of the cable connector 1 is fully inserted in the PCB connector 101, the connectors 1, 101 latch together. In particular, the outer shell 5a has a number of indentations that resiliently bias the rails 107 of the PCB connector 1 during insertion. Once fully inserted, the rails 107 are able to move back to their neutral position directly above the indentations, thereby retaining the cable connector 1.

The connectors 1, 101 may be unlatched by inserting a tool through small holes in the upper surface of the shell 5a to bias the rails 107 of the PCB connector 101 and release the indentations, and thus the cable connector 1.

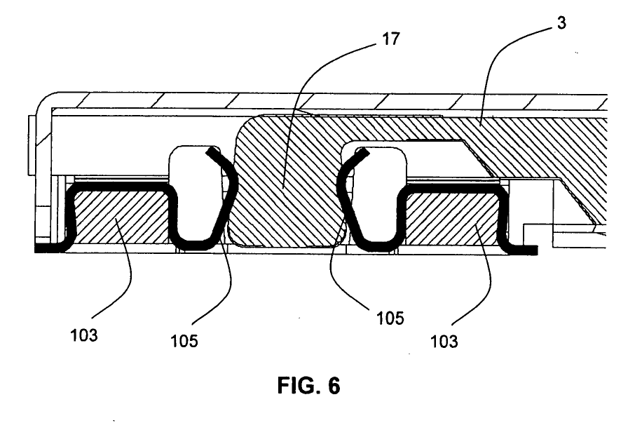

FIG. 6 is a cross sectional view showing the connectors 1, 101 in the mated condition. As can be seen, the downwards protrusion 17 is wedge shaped with sides that taper to be wider at its end. As a consequence of this shape, when the contacts 105 of the PCB connector 101 apply a lateral force on the sides of the downwards protrusion 17, there is a net downwards force on the downwards protrusion 17 which maintains the connectors 1, 101 firmly in engagement. Because of the hooked shape of the contacts 105 of the PCB connector 101, a snap fit between the connectors 1, 101 is also achieved.

Specific embodiments of the invention has been described above in detail. However, various changes and modifications within the scope of the invention will be apparent to those skilled in the art.

For example, connectors may have different numbers of tracks and contacts to those described above.

In the embodiments described above, each of the first and second tracks terminate in a solder terminal for connection to the conductors of coaxial cables. In alternative embodiments, the tracks may terminate in terminals for connection to the conductors of coaxial cables using conductive adhesives.

Although particular embodiments of the invention have been described and illustrated herein, it is recognized that modifications and variations may readily occur to those skilled in the art, and consequently, it is intended that the claims be interpreted to cover such modifications and equivalents.

What is claimed is:

1. A coaxial connector comprising an injection moulded substrate and a plated conductive pattern formed directly on the substrate, wherein the conductive pattern comprises a first plurality of tracks each terminating at one end in a connecting portion for connection to an inner conductor of a coaxial 5 cable and at the other end in a pad for contacting a mating connector.

2. A connector according to claim 1, wherein the conductive pattern further comprises a plurality of second tracks each terminating at one end in a connecting portion for connection to an outer conductor of a coaxial cable, the other end being connected to a pad for contacting a mating connector.

3. A connector according to claim 2, wherein the first tracks and the second tracks are arranged alternately across the substrate.

4. A connector according to claim 2 or 3, wherein the second tracks are connected together by a link track extending perpendicular to the second tracks, the second tracks sharing at least one pad.

5. A connector according to claim 4, further comprising a conductive cover which encloses the substrate, the conductive cover being electrically connected to the second tracks.

6. A connector according to claim 2 or 3, wherein groups of the second tracks are connected together by respective link tracks each extending perpendicular to the second tracks.

7. A connector according to claim 6, wherein different groups of the second tracks are for connection to different electrical potentials.

8. A connector according to any of claims 2 to 7, wherein the connecting portions for the first and second tracks are spaced across upper and lower sides of the substrate, thereby providing two rows of connections.

9. A connector according to claim 8, wherein the pads for the first and second tracks are arranged in first and second rows, the first and second rows being associated with the connecting portions on the upper and lower sides of the substrate, respectively.

10. A connector according to any of claims 2 to 9, wherein the rows of pads for the first and second tracks are formed on opposite sides of a downwards protrusion of the substrate.

11. A connector according to claim 10, wherein the sides of the protrusion are tapered with respect to each other, such that external lateral forces on the rows of pads cause a downwards force on the protrusion for maintaining engagement with a mating connector.

12. A connector according to claim 1, further comprising a conductive cover which encloses the substrate.

13. A connector arrangement comprising a cable connector according to claim 11 and a mating connector, wherein the mating connector comprises two rows of resilient contacts arranged for contacting and applying opposing lateral forces to respective rows of the pads of the first connector, such that engagement of the first conductor can be positively maintained.

14. A connector arrangement according to claim 13, wherein the mating conductor is adapted for connection to a printed circuit board.

15. A connector arrangement according to claim 13 or 14, wherein the first connector and the mating connector have a latching mechanism for latching the connectors together in the engaged position.
